(19) United States
(12) Patent Application Publication
(10) Pub. No.: US 2026/0221356 A1
(43) Pub. Date: Jul. 30, 2026

(54) ELECTRICAL SWITCH ASSEMBLY

(71) Applicant: MOTOMOTION CHINA CORPORATION, CHANGZHOU (CN)

(72) Inventors: CHIH HSIUNG LIU, BENONI (ZA); YIN ZAO PENG, CHANGZHOU (CN)

(21) Appl. No.: 19/040,815

(22) Filed: Jan. 29, 2025

(51) Int. Cl. H01H 13/14; H01H 13/04; H05K 7/14

(52) U.S. Cl. CPC H01H 13/14; H01H 13/04; H05K 7/1427

(57) ABSTRACT

A new and improved electrical switch assembly comprises a housing, a printed circuit board mounted within the housing, the printed circuit board comprising a first circuit portion, a second circuit portion separated from the first circuit portion such that a circuit, comprising the first circuit portion and the second circuit portion, is normally OPEN. A snap dome-type momentary switch contact is electrically connected to the second circuit portion, and an operator button is movably mounted upon the housing for movement into contact with the first circuit portion such that the circuit is CLOSED as a result of the first and second circuit portions being electrically connected together by the snap dome-type momentary switch contact.

### FIELD OF THE INVENTION

The present invention relates generally to electrical switch assemblies, and more particularly to a new and improved push-button type electrical switch assembly which is more reliable and easier to use than conventional push-button electrical switch assemblies in view of the fact that the distance that the push-button component of the new and improved electrical switch needs to travel, in order to close the circuit, has been significantly reduced.

### BACKGROUND OF THE INVENTION

Push-button electrical switches are of course well-known, however, some push-button electrical switches are somewhat difficult to operate, or are unreliable in their operation. For example, with reference being made to FIG. 1, a conventional, PRIOR ART push-button electrical switch assembly is disclosed and is generally indicated by the reference character 100. More particularly, the conventional PRIOR ART push-button electrical switch assembly 100 is seen to comprise a tubular housing 102 and a base 104 which comprises an upstanding tubular support 106 around which the lower end of the tubular housing 102 is adapted to be disposed when the electrical switch assembly 100 is assembled together, and an integrally attached flanged, tubular foundation or foot 108 upon which the lower edge portion of the tubular housing 102 will be engaged and supported when the electrical switch assembly 100 is assembled together. In addition, it is seen that the innards of the electrical switch assembly 100 comprises an electrical switch mechanism 110 and an electrical switch circuit housing 112 within which the electrical circuits and printed circuit board are disposed. It is seen that the electrical switch circuit housing 112 comprises a lower cylindrical housing portion 114 which is adapted to be inserted into a central through-bore portion 116 of the tubular support portion of the base 104, while a radially outwardly extending annular flanged portion 118 of the electrical switch circuit housing 112 effectively defines an annular shoulder portion which is adapted to be seated upon an annular upper edge portion 120 of the upstanding tubular support 106 so as to ensure that the electrical switch circuit housing 112 is in fact properly seated within and upon the upstanding tubular support 106 when the electrical switch assembly 100 is assembled together. Continuing further, it is also seen that electrical connectors 122 extend outwardly from the lower distal end portion of the electrical switch circuit housing 112 such that after the electrical switch circuit housing 112 is operatively mounted within the base 104, the electrical connectors 122 will be electrically connected to a suitable power source.

Lastly, an operator button 124 is mounted within the upper end portion of the tubular housing 102 such that the upper end or crown portion 126 of the operator button 124 projects outwardly from a central opening 128 defined within the uppermost or head end of the tubular housing 102, while the undersurface portion of the operator button 124 is engaged with and sits atop the upper end portion 130 of the electrical switch mechanism 110. When the electrical switch mechanism 110 is disposed in the illustrated state, the electrical circuit is OPEN, while when the operator button 124 is depressed so as to move the electrical switch mechanism 110 downwardly, the electrical switch mechanism 110 will make contact with the printed circuit board disposed within the electrical switch circuit housing 112 such that the electrical circuit will then be CLOSED. Release of the operator button 124 will of course permit the electrical circuit to return to its OPEN state. It can readily be appreciated, however, that in view of the fact that the electrical switch mechanism 110 must undergo a significant displacement in order to effectively change the electrical circuit from an OPEN circuit to a CLOSED circuit, sometimes that task is not necessarily accomplished immediately, or as a result of the first time that the user/operator depresses the operator button 124, thereby necessitating an enhanced depression force to be applied to the operator button 124, or alternatively, that multiple and repeated attempts to implement proper actuation of the electrical switch mechanism 110 must be initiated so as to in fact achieve the closure of the electrical circuit.

A need therefore exists in the art for a new and improved electrical switch assembly. Another need exists in the art for a new and improved electrical switch assembly wherein the structure of the switch is simplified as compared to conventional electrical switch assemblies. Still another need exists in the art for a new and improved electrical switch assembly wherein the structure of the switch is simplified as compared to conventional electrical switch assemblies, and wherein the displacement of the electrical switch mechanism is substantially reduced. Yet another need exists in the art for a new and improved electrical switch assembly wherein the structure of the switch is simplified as compared to conventional electrical switch assemblies, and wherein the displacement of the electrical switch mechanism is substantially reduced so that only a minimal amount of force needs to be applied to the operator button in order to render the electrical switch mechanism operative. Still yet another need exists in the art for a new and improved electrical switch assembly wherein the structure of the switch is simplified as compared to conventional electrical switch assemblies, and wherein the displacement of the electrical switch mechanism is substantially reduced so that only a minimal amount of force needs to be applied to the operator button in order to render the electrical switch mechanism operative whereby the electrical circuit, controlled by means of the electrical switch mechanism, can be moved from an OPEN state to a CLOSED state. Yet still another need exists in the art for a new and improved electrical switch assembly wherein the structure of the switch is simplified as compared to conventional electrical switch assemblies, and wherein the displacement of the electrical switch mechanism is substantially reduced so that only a minimal amount of force needs to be applied to the operator button in order to render the electrical switch mechanism operative whereby the electrical circuit, controlled by means of the electrical switch mechanism, can be moved from an OPEN state to a CLOSED state in a reliable manner. A further need exists in the art for a new and improved electrical switch assembly wherein the structure of the switch is simplified as compared to conventional electrical switch assemblies, and wherein the displacement of the electrical switch mechanism is substantially reduced so that only a minimal amount of force needs to be applied to the operator button in order to render the electrical switch mechanism operative whereby the electrical circuit, controlled by means of the electrical switch mechanism, can be moved from an OPEN state to a CLOSED state in a reliable manner, the first time that the operator button is depressed, thereby rendering multiple attempts to successfully operate the electrical switch mechanism unnecessary.

### OVERALL OBJECTIVES OF THE INVENTION

A first overall objective of the present invention is to provide a new and improved electrical switch assembly. Another overall objective of the present invention is to provide a new and improved electrical switch assembly wherein the structure of the switch is simplified as compared to conventional electrical switch assemblies. Still another overall objective of the present invention is to provide a new and improved electrical switch assembly wherein the structure of the switch is simplified as compared to conventional electrical switch assemblies, and wherein the displacement of the electrical switch mechanism is substantially reduced. Yet another overall objective of the present invention is to provide a new and improved electrical switch assembly wherein the structure of the switch is simplified as compared to conventional electrical switch assemblies, and wherein the displacement of the electrical switch mechanism is substantially reduced so that only a minimal amount of force needs to be applied to the operator button in order to render the electrical switch mechanism operative. Still yet another overall objective of the present invention is to provide a new and improved electrical switch assembly wherein the structure of the switch is simplified as compared to conventional electrical switch assemblies, and wherein the displacement of the electrical switch mechanism is substantially reduced so that only a minimal amount of force needs to be applied to the operator button in order to render the electrical switch mechanism operative whereby the electrical circuit, controlled by means of the electrical switch mechanism, can be moved from an OPEN state to a CLOSED state. Yet still another overall objective of the present invention is to provide a new and improved electrical switch assembly wherein the structure of the switch is simplified as compared to conventional electrical switch assemblies, and wherein the displacement of the electrical switch mechanism is substantially reduced so that only a minimal amount of force needs to be applied to the operator button in order to render the electrical switch mechanism operative whereby the electrical circuit, controlled by means of the electrical switch mechanism, can be moved from an OPEN state to a CLOSED state in a reliable manner. A further overall objective of the present invention is to provide a new and improved electrical switch assembly wherein the structure of the switch is simplified as compared to conventional electrical switch assemblies, and wherein the displacement of the electrical switch mechanism is substantially reduced so that only a minimal amount of force needs to be applied to the operator button in order to render the electrical switch mechanism operative whereby the electrical circuit, controlled by means of the electrical switch mechanism, can be moved from an OPEN state to a CLOSED state in a reliable manner, the first time that the operator button is depressed, thereby rendering multiple attempts to successfully operate the electrical switch mechanism unnecessary.

### SUMMARY OF THE INVENTION

The foregoing and other objectives are achieved in accordance with the principles and teachings of the present invention through the provision of a new and improved electrical switch assembly which comprises a housing, an operator button operably disposed within the upper end of housing, and a printed circuit board having a first axially central circular inner circuit formed thereon, and a second radially outer annular circuit formed thereon, wherein the first axially central inner circuit and the second radially outer, annular circuit are spaced from each other by means of an annular insulative portion of the printed circuit board. In addition, a snap dome-type momentary switch contact is operably mounted upon the printed circuit board, and a base completes the new and improved electrical switch assembly. Snap dome-type momentary switch contacts are well-known metal switches that provide tactile feedback when depressed so that the user/operator can in fact sense that the switch has in fact been successfully depressed. Snap-dome type momentary switches are normally fabricated from stainless steel and exhibit high life cycle performance ratings. In the present invention electrical switch assembly, the snap dome-type momentary switch contact is electrically connected only to the second radially outer annular circuit such that the electrical circuit, controlled by means of the first axially central inner circuit and the second radially outer annular circuit, is normally OPEN, however, when the snap dome-type momentary switch contact is depressed, it will engage the first axially central inner circuit such that the electrical circuit, controlled by means of the first axially central inner circuit and the second radially outer annular circuit, will now be CLOSED. Release of the force or pressure exerted upon the snap dome-type momentary switch contact by the user or operator will permit the snap dome-type momentary switch contact to effectively snap back to its non-depressed state whereby, once again, the electrical circuit, controlled by means of the first axially central inner circuit and the second radially outer annular circuit, will be OPEN,

The housing comprises a radially outer tubular housing and a radially inner tubular housing which is concentric with the radially outer tubular housing and which has its upper end portion integrally connected to the upper end portion of the radially outer tubular housing such that the radially inner tubular housing effectively depends, or extends vertically downwardly, from an upper, radially outwardly extending annular flanged section of the housing to an extent which is almost one half the depth or vertical height of the housing. The operator button is inserted into the top of the radially inner tubular housing so as to thereafter effectively be mounted within the radially inner tubular housing, while the printed circuit board and the base are inserted upwardly through the bottom portion of the radially outer tubular housing. When the new and improved electrical switch assembly is assembled together, and the operator button is depressed, the lower end portion of the operator button will engage the snap dome-type momentary switch contact disposed upon the printed circuit board and momentarily connect the first axially central inner circuit and the second radially outer annular circuit together so as to alter the electrical circuit from a normally OPEN circuit to a momentarily CLOSED circuit.

### BRIEF DESCRIPTIONS OF THE DRAWINGS

Various other features and attendant advantages of the present invention will be more fully appreciated from the following detailed description when considered in connection with the accompanying drawings in which like reference characters designate like or corresponding parts throughout the several views, and wherein:

FIG. 1 is an exploded view of a conventional PRIOR ART electrical switch assembly;

FIG. 2 is an exploded view of a new and improved electrical switch assembly as constructed in accordance with the principles and teachings of the present invention;

FIG. 3 is a cross-sectional view of the electrical switch assembly housing as illustrated within FIG. 2;

FIG. 4 is a perspective view of the electrical switch assembly, as illustrated within FIG. 2, fully assembled;

FIG. 5 is a cross-sectional view of the electrical switch assembly, fully assembled, as illustrated within FIG. 2; and

FIG. 6 is an enlarged perspective view of the circuit board of the electrical switch assembly, as illustrated within FIG. 2, wherein the first and second, inner and outer circuits, are defined upon the circuit board.

### DETAILED DESCRIPTION OF THE PREFERRED EMBODIMENT

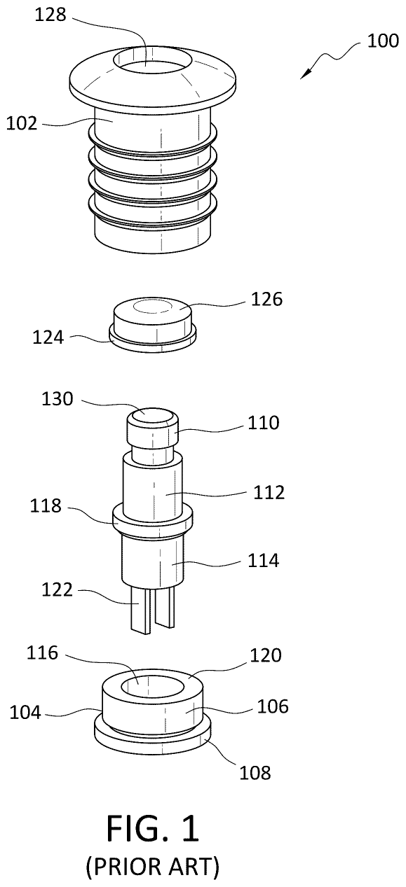

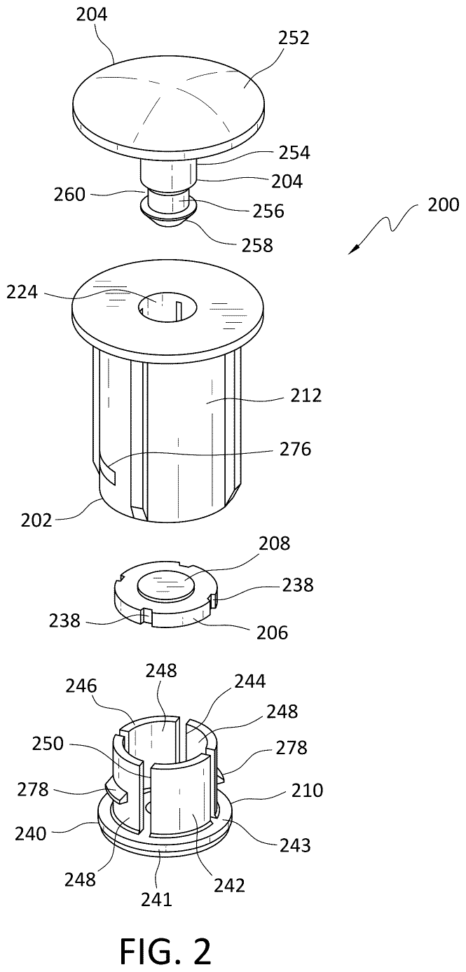

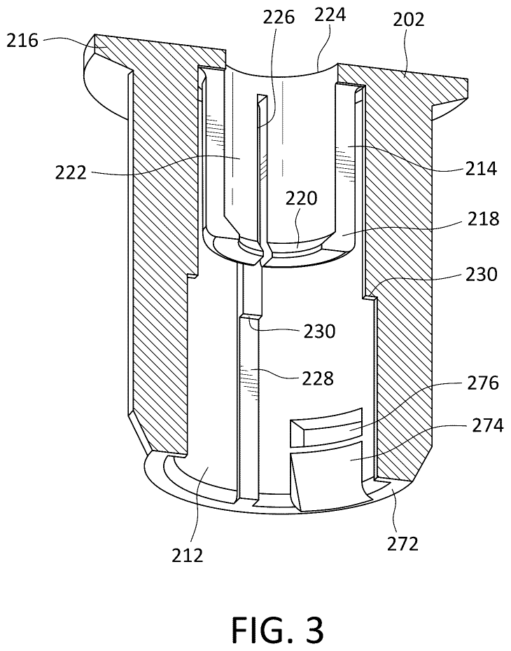

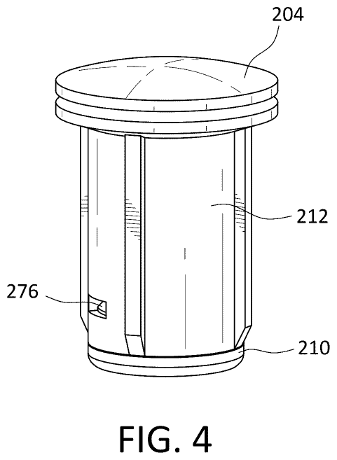

Referring now to the drawings, and more particularly to FIGS. 1-6, a new and improved electrical switch assembly is disclosed and is generally indicated by the reference character 200. More particularly, it is seen that the new and improved electrical switch assembly 200 comprises a housing 202, an operator button 204 operably disposed within the upper end of housing 202, a printed circuit board 206, a snap dome-type momentary switch contact 208 operably mounted upon the printed circuit board 206, and a base 210. As can best be appreciated from FIGS. 2 and 3, the electrical switch assembly housing 202 is seen to comprise a radially outer tubular housing 212, and a radially inner tubular housing 214 which is concentric with the radially outer tubular housing 212 and which has its upper end portion integrally connected to the upper end portion of the radially outer tubular housing 212 such that the radially inner tubular housing 214 effectively depends, or extends vertically downwardly, from an upper, radially outwardly extending annular flanged section 216 of the housing 202 to an extent which is almost one half the depth or vertical extent of the housing 202. In addition, it is seen that the lower end portion of the radially inner tubular housing 214 comprises a radially inwardly extending annular flanged portion 218 in connection with which there is also defined an annular ramp or sloped section 220 which integrally interconnects the radially inwardly extending annular flanged portion 218 to the interior vertical wall portion 222 of the radially inner tubular housing 214, while the upper end portion of the housing 202 is provided with an axially located hole or aperture 224 which leads into, and corresponds with, the hollow interior portion of the radially inner tubular housing 214. Still further, it is seen that a plurality of slits 226 are defined within the peripheral wall structure of the radially inner tubular housing 214 so as to extend vertically upwardly from the radially inwardly extending annular flanged portion 218 toward the hole or aperture 224 defined within the upper end portion of the housing 202. In this manner, it can be appreciated that the plurality of slits 226 effectively divide the peripheral wall structure of the radially inner tubular housing 214 into relatively independent flexible wall sections, for a purpose which will be described hereinafter, wherein it will be appreciated that the radially inwardly extending annular flanged portion 218 effectively comprises a plurality of circumferentially spaced, arcuate radially inwardly extending flanged portions 218. Lastly, as can best be appreciated from FIG. 3, a plurality of circumferentially spaced, vertically extending ribs 228 are provided upon interior wall portions of the radially outer tubular housing 212, and that intermediate portions of the vertically extending ribs 228 are provided with shoulder portions 230 which are disposed at an elevational level beneath the radially inwardly extending annular flanged portion 218 of the radially inner tubular housing 214, all for a purpose which will be fully explained hereinafter.

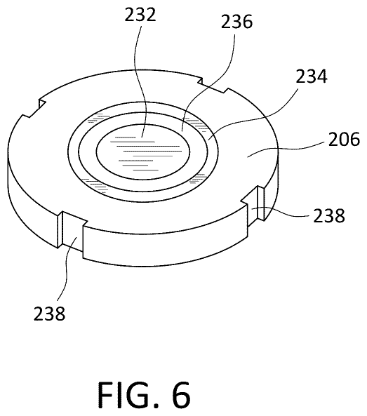

With reference now being made to FIGS. 2 and 6, the specific structure of the printed circuit board 206 will now be described. More particularly, it is seen that the printed circuit board 206 has a first axially central circular inner circuit portion 232 formed thereon, and a second radially outer annular circuit portion 234 formed thereon, wherein the first axially central inner circuit portion 232 and the second radially outer, annular circuit portion 234 are spaced from each other by means of an annular insulative portion 236 of the printed circuit board 206. Still further, it is also seen, and to be understood, that the snap dome-type momentary switch contact 208 is a well-known metal switch that provides tactile feedback when depressed so that the user/operator can in fact sense that the switch has in fact been successfully depressed. Snap-dome type momentary switches are normally fabricated from stainless steel and exhibit high life cycle performance ratings. In the present invention electrical switch assembly 100, the snap dome-type momentary switch contact 208 is electrically connected only to the second radially outer annular circuit portion 234 such that the electrical circuit, controlled by means of the first axially central inner circuit portion 232 and the second radially outer annular circuit portion 234, is normally OPEN, however, when the snap dome-type momentary switch contact 208 is forced downwardly, it will elastically deform and engage the first axially central inner circuit portion 232 such that the electrical circuit, controlled by means of the first axially central inner circuit portion 232 and the second radially outer annular circuit portion 234, will now be CLOSED. Release of the force or pressure exerted upon the snap dome-type momentary switch contact 208 by the user or operator, as will be explained more fully hereinafter, will permit the snap dome-type momentary switch contact 208 to effectively snap back to its non-deformed state whereby, once again, the electrical circuit, controlled by means of the first axially central inner circuit portion 232 and the second radially outer annular circuit portion 234, will again be OPEN. It is lastly noted, as can best be seen in FIG. 6, that the outer circumferential or peripheral edge surface of the printed circuit board 206 is provided with a plurality of circumferentially spaced notches 238 which are adapted to respectively receive or accommodate the plurality of circumferentially spaced, vertically extending ribs 228, provided upon the interior wall portions of the radially outer tubular housing 212, when the electrical switch assembly 200 is assembled together, as will be more fully described hereinafter.

Referring back to FIG. 2, the base 210 is seen to comprise a circular platform 240 upon which an upstanding annular wall 242 is fixedly attached at a radial position located radially inwardly from the circumferential or peripheral surface 241 of the platform 240 such that an annular flanged portion 243 is defined between the circumferential or peripheral surface 241 of the platform 240 and the upstanding annular wall 242. In reality, a plurality of circumferentially spaced slits 244, extending downwardly from the upper edge portion 246 of the upstanding annular wall 242 to the platform 240, are formed within the upstanding annular wall 242 so as to effectively divide the upstanding annular wall 242 into a plurality of circumferentially spaced upstanding wall sections 248, each one of which has an arcuate configuration as seen from a plan perspective or a horizontal cross-sectional perspective. Still further, it can be readily appreciated that all of the circumferentially spaced upstanding wall sections 248 are effectively independent of each other, and therefore, each one of the circumferentially spaced upstanding wall sections 248 can flex with respect to each other, for a purpose which will be described hereinafter. Lastly with respect to the base 210, an axially central hole or aperture 250 is defined within the circular platform 240 so as to permit a suitable electrical cable, for providing electrical power to the printed circuit board 206, to pass therethrough and into the interior of the electrical switch assembly 200.

To complete the structure of the electrical switch assembly 200, the operator button 204 is seen to comprise a pushbutton cap 252, a first dependent shaft section 254 integrally connected to an undersurface portion of the pushbutton cap 252, a second dependent shaft section 256 integrally connected to the lower end portion of the first dependent shaft section 254, and a distal conical frustum head section 258 integrally connected to the lower end portion of the second dependent shaft section 256. As will be described more fully hereinafter, the distal conical frustum head section 258 serves as an actuator which is adapted to engage the snap dome-type momentary switch contact 208 in order to move the snap dome-type momentary switch contact 208 into contact with the first axially central inner circuit portion 232 in order to CLOSE the electrical circuit defined between the first axially central inner circuit portion 232 and the second radially outer annular circuit portion 234 when the pushbutton cap 252 is depressed. Lastly, it is noted that the external diametrical extent of the second dependent shaft section 256 is less than the external diametrical extent of the first dependent shaft section 254 such that the relatively smaller external diametrical extent of the second dependent shaft section 256 effectively defines an annular recess region 260, the purpose of which will be described hereinafter.

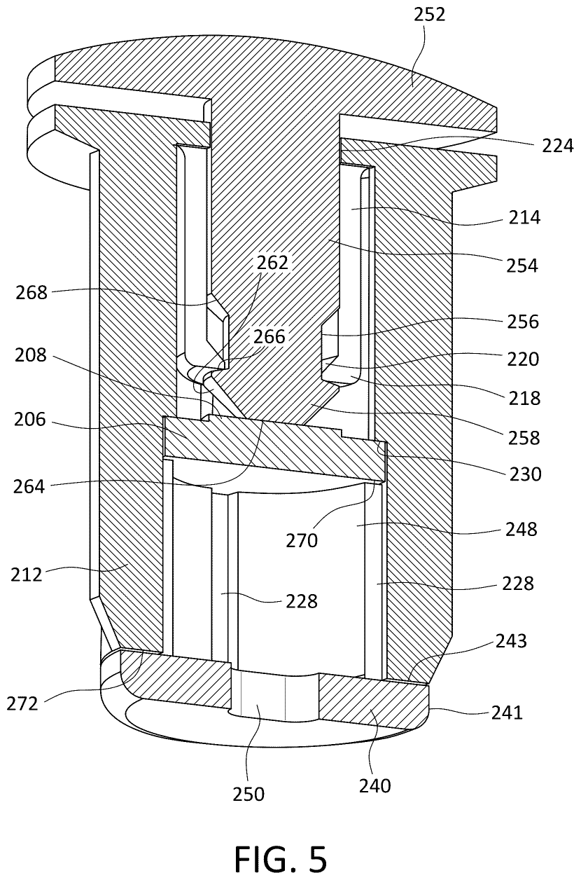

Having described substantially all of the structural components comprising the new and improved electrical switch assembly 200, the assembly process for assembling the new and improved electrical switch assembly 200 will now be described. More particularly, the operator button 204 is effectively assembled into the housing 202 as a result of inserting the distal conical frustum head section 258, and the first and second shaft sections 254, 256, of the operator button 204 into and through the aperture or hole 224 defined within the upper end portion of the housing 202. As a result of this operation, and with reference best being made to FIG. 5, it is seen that the annular conical surface 262 of the distal conical frustum head section 258 will encounter the plurality of radially inwardly extending arcuate flanged portions 218 of the radially inner tubular housing 214 whereby, as a result of such an encounter, the annular conical surface 262 of the distal conical frustum head section 258 will effectively act as a cam to force the plurality of radially inwardly extending arcuate flanged portions 218 of the radially inner tubular housing 214 to act as cam followers and move or be displaced radially outwardly thereby permitting the annular conical surface 262 of the distal conical frustum head section 258 to pass axially beyond the plurality of radially inwardly extending arcuate flanged portions 218 of the radially inner tubular housing 214 whereby the distal planar surface portion 264 of the distal conical frustum head section 258 will be able to engage the snap dome-type momentary switch contact 208 mounted upon the printed circuit board 206.

In addition, it is also seen that once the annular conical surface 262 of the distal conical frustum head section 258 has passed beyond the plurality of radially inwardly extending arcuate flanged portions 218 of the radially inner tubular housing 214, the radially inwardly extending arcuate flanged portions 218 of the radially inner tubular housing 214 will effectively return to their original non-displaced positions whereby the radially inwardly extending arcuate flanged portions 218 of the radially inner tubular housing 214 will now be disposed within the annular recess region 260. In this manner, it will be further appreciated that as the operator button 208 moves or reciprocates axially upwardly and downwardly, when axially depressed so as to effectively CLOSE the circuit defined between the first axially central inner circuit portion 232 and the second radially outer annular circuit portion 234, or when released so as to permit the circuit defined between the first axially central inner circuit portion 232 and the second radially outer annular circuit portion 234 to be OPEN, the plurality of radially inwardly extending arcuate flanged portions 218 of the radially inner tubular housing 214 will effectively move, or be accommodated, in a relative manner, within the annular space or region 260 defined between the first and second shaft sections 254,256 of the operator button 204. It is to be further appreciated that upward movement of the operator button 204, relative to plurality of radially inwardly extending arcuate flanged portions 218 of the radially inner tubular housing 214, is effectively limited or defined by the base portion 266 of the distal conical frustum head section 258 encountering undersurface portions of all of the radially inwardly extending arcuate flanged portions 218 of the radially inner tubular housing 214. In a similar but opposite manner, downward movement of the operator button 204, relative to plurality of radially inwardly extending arcuate flanged portions 218 of the radially inner tubular housing 214, is effectively limited or defined by an annular conical surface portion 268, which integrally and smoothly interconnects the first and second shaft sections 254, 256 of the operator button 204, and which encounters the plurality of sloped or ramp sections 220 that integrally interconnect the plurality of radially inwardly extending arcuate flanged portions 218 to the interior vertical wall portions 222 of the radially inner tubular housing 214.

Continuing further, in order to assemble the printed circuit board 206 into the electrical switch assembly 200, the printed circuit board 206, having the snap dome-type momentary switch contact 208 mounted thereon, is inserted upwardly into the electrical switch housing 202, as a result of being inserted into the lower open end of the radially outer tubular housing 212, wherein it is to be appreciated that the plurality of circumferentially spaced notches 238, which are defined within the outer circumferential or peripheral edge surface of the printed circuit board 206, are adapted to respectively receive or accommodate the plurality of circumferentially spaced, vertically extending ribs 228 provided upon the interior wall portions of the radially outer tubular housing 212, whereby the printed circuit board 206 will be inserted into the electrical switch housing 202 until circumferentially spaced upper peripheral edge portions of the printed circuit board 206 encounter the shoulder portions 230 defined upon the plurality of vertically extending ribs 228. Subsequently, the base 210 is inserted into the electrical switch housing 202 as a result of being inserted into the lower open end of the radially outer tubular housing 212, wherein the plurality of circumferentially spaced slits 244, extending downwardly from the upper edge portions 246 of the plurality of circumferentially spaced upstanding wall sections 248 of the upstanding annular wall 242 to the platform 240, will similarly accommodate the plurality of vertically extending ribs 228 of the radially outer tubular housing 212. When properly and fully assembled, the upper edge portions 246 of the plurality of circumferentially spaced upstanding wall sections 248 of the upstanding annular wall 242 will engage outer peripheral, undersurface edge portions 270 of the printed circuit board 206 while, at the same time, annular flanged portion 243 of the base 210 will engage the lower annular end portion 272 of the radially outer tubular housing 212.

Lastly, in order to effectively ensure that all of the aforenoted components of the new and improved electrical switch assembly 200 are in fact properly assembled together, and that they remain together in their assembled state, it is noted, as can best be appreciated from FIGS. 2 and 3, that a plurality of equiangularly spaced, right-triangular cam deflectors 274 are fixedly mounted upon lower end interior wall portions of the radially outer tubular housing 212, and a plurality of equiangularly spaced, rectangular-shaped holes or apertures 276 are defined within the lower end portions of the radially outer tubular housing 212 at positions disposed immediately above the plurality of equiangularly spaced, right-triangular deflectors 274. In a similar manner, a plurality of equiangularly spaced, right-triangular cam followers 278 are fixedly mounted upon respective exterior wall portions of each one of the plurality of circumferentially spaced upstanding wall sections 248. Accordingly, as the base 210 is inserted into the electrical switch housing 202, the plurality of equiangularly spaced, right-triangular cam followers 278 will respectively engage the plurality of equiangularly spaced, right-triangular deflectors 274 causing the plurality of circumferentially spaced upstanding wall sections 248 to be deflected radially inwardly. When the base 210 has been inserted a sufficient axial extent into the electrical switch housing 202, the plurality of equiangularly spaced, right-triangular cam followers 278 will bypass the plurality of equiangularly spaced, right-triangular deflectors 274, thereby permitting the plurality of circumferentially spaced upstanding wall sections 248 to effectively return to their original, non-deflected positions at which the plurality of equiangularly spaced, right-triangular cam followers 278 will effectively snap into the plurality of equiangularly spaced, rectangular-shaped holes or apertures 276. Accordingly, at this point in time, the base 210 is fixedly mounted and secured within the electrical switch housing 202.

Obviously, many variations and modifications of the present invention are possible in light of the above teachings. It is therefore to be understood that within the scope of the appended claims, the present invention may be practiced otherwise than as specifically described herein.

What is claimed is:

1. An electrical switch assembly, comprising:
a housing;
a printed circuit board mounted within said housing, said printed circuit board comprising a first circuit portion, a second circuit portion separated from said first circuit portion such that a circuit, comprising said first circuit portion and said second circuit portion, is normally OPEN;
a snap dome-type momentary switch contact electrically connected to said second circuit portion; and
an operator button movably mounted upon said housing for movement into contact with said snap dome-type momentary switch contact such that said circuit is CLOSED as a result of said first and second circuit portions being electrically connected together by said snap dome-type momentary switch contact.

2. The electrical switch assembly as set forth in claim 1, wherein:
said operator button is adapted to be inserted into an upper end portion of said housing.

3. The electrical switch assembly as set forth in claim 1, wherein:
said housing comprises a radially outer tubular housing, and a radially inner tubular housing.

4. The electrical switch assembly as set forth in claim 1, wherein:
said operator button is adapted to be inserted into an upper end portion of said radially inner tubular housing.

5. The electrical switch assembly as set forth in claim 4, wherein:
said radially inner housing is divided into a plurality of independently flexible sections so as to permit said operator button to be inserted into and mounted upon said radially inner tubular housing.

6. The electrical switch assembly as set forth in claim 5, wherein:
a plurality of circumferentially spaced, arcuate radially inwardly extending flanged portions are defined upon each one of said plurality of independently flexible sections of said radially inner housing; and
said operator button comprises a distal head section for encountering said plurality of circumferentially spaced, arcuate radially inwardly extending flanged portions of said independently flexible sections of said radially inner housing so as to deflect said independently flexible sections of said radially inner housing to flex radially outwardly in order to permit said operator button to be mounted within said radially inner housing.

7. The electrical switch assembly as set forth in claim 3, wherein:
said operator button is movably mounted upon said radially inner housing between a depressed state or position and a non-depressed state or position.

8. The electrical switch assembly as set forth in claim 7, wherein:
when said operator button is moved to said depressed state or position, said operator button will engage said snap dome-type momentary switch contact such that said circuit is CLOSED as a result of said first and second circuit portions being electrically connected together by said snap dome-type momentary switch contact.

9. The electrical switch assembly as set forth in claim 3, wherein:
said printed circuit board is adapted to be inserted into a lower end portion of said housing.

10. The electrical switch assembly as set forth in claim 9, wherein:
said radially outer housing comprises a plurality of ribs; and
outer peripheral surface portions of said printed circuit board are provided with a plurality of notches for accommodating said plurality of ribs of said radially outer housing so that said printed circuit board can be mounted upon said radially outer housing.

11. The electrical switch assembly as set forth in claim 10, wherein:
said plurality of ribs comprise shoulder portions which are adapted to be engaged by outer peripheral edge portions of said printed circuit board such that said printed circuit is properly seated within said radially outer housing.

12. The electrical switch assembly as set forth in claim 3, further comprising:
a base mounted within a lower end portion of said housing.

13. The electrical switch assembly as set forth in Claim12, wherein said base comprises:
a platform; and
an upstanding annular wall portion mounted upon said platform at a position radially inward from an outer circumferential edge portion of said platform so as to define an annular flanged portion.

14. The electrical switch assembly as set forth in claim 13, wherein:
said upstanding annular wall portion of said base is divided into a plurality of independently flexible sections so as to permit said base to be inserted into and mounted upon said radially outer tubular housing.

15. The electrical switch assembly as set forth in claim 14, further comprising:
a plurality of cams fixedly mounted upon interior wall portions of said radially outer tubular housing; add
a plurality of cam followers fixedly mounted upon exterior wall portions of said plurality of independently flexible sections of said upstanding annular wall portion of said base for causing said plurality of independently flexible sections of said upstanding annular wall portion of said base to flex radially inwardly, as a result of said plurality of cam followers, fixedly mounted upon exterior wall portions of said plurality of independently flexible sections of said upstanding annular wall portion of said base, encountering said plurality of cams, fixedly mounted upon interior wall portions of said radially outer tubular housing, so as to permit said base to be inserted into said radially outer tubular housing.

16. The electrical switch assembly as set forth in claim 15, further comprising:
a plurality of holes defined within said interior wall portions of said radially outer tubular housing for receiving said plurality of cam followers, fixedly mounted upon exterior wall portions of said plurality of independently flexible sections of said upstanding annular wall portion of said base, so as to secure said base within said radially outer tubular housing.

17. The electrical switch assembly as set forth in claim 13, wherein:
said annular flanged platform of said base engages an annular bottom edge portion of said radially outer tubular housing when said base is fully inserted into said radially outer tubular housing.

18. The electrical switch assembly as set forth in claim 13, further comprising:
a hole defined within said platform of said base for permitting an electrical cable to be routed into said radially outer tubular housing for providing electrical power to said printed circuit board.
